(19) United States
(12) Patent Application Publication
(10) Pub. No.: US 2020/0412166 A1
(43) Pub. Date: Dec. 31, 2020

(54) CIRCUIT STRUCTURE FOR SWITCHING PLURAL POWER SUPPLY UNITS BETWEEN SERIES-CONNECTED AND PARALLEL-CONNECTED CONFIGURATIONS

(71) Applicant: Phei Kuan Electronic Co., Ltd., New Taipei City (TW)

(72) Inventor: Ming-Chan CHEN, New Taipei City (TW)

(73) Assignee: Phei Kuan Electronic Co., Ltd., New Taipei City (TW)

(21) Appl. No.: 16/666,509

(22) Filed: Oct. 29, 2019

(30) Foreign Application Priority Data
Jun. 28, 2019 (TW) 108122925

(51) Int. Cl. H02J 9/06; H03K 17/60; H03K 17/687; H03K 17/72

(52) U.S. Cl. CPC H02J 9/061; H03K 17/60; H03K 2017/515; H03K 17/72; H03K 17/687

(57) ABSTRACT

A circuit structure applied to a driver of an electronic device and for switching power supply units between series-connected and parallel-connected configurations includes an electricity output portion having a first end and a second end, two power supply units, and a switch unit. Each power supply unit includes an electricity element having a positive electrode and a negative electrode, a front diode having an anode connected to the positive electrode and a cathode electrically connected to the first end, and a rear diode having a cathode connected to the negative electrode and an anode electrically connected to the second end. The switch unit has a first end and a second end respectively connected to the positive electrode of one electricity element and the negative electrode of the other electricity element, and a closed-circuit state and an open-circuit state when the electricity elements are respectively series-connected or parallel-connected to output electricity.

### CROSS-REFERENCE TO RELATED APPLICATIONS

This application claims priority to Taiwan Patent Application No. 108122925 filed on Jun. 28, 2019, the entire disclosures of which are expressly incorporated herein by reference.

### FIELD

The present disclosure relates generally to circuit structures, and more particularly to a circuit structure in which a switch unit can be switched between different states in order to convert a plurality of power supply units into a series-connected or parallel-connected configuration.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The rapid development of power electronics and the advancement of high-tech industries have brought about increasingly versatile electronic products with more and more affordable prices, and these products have been extensively used by companies as well as individual users, either for work or for play. However, electronic products tend to pose the following two problems in use. First, an electronic product cannot work when its operating power frequency is different from the frequency of mains electricity. Second, when a power outage takes place unexpectedly, an electronic product in operation may be shut down improperly without saving the data in use. Either of the above can be a serious issue for the product user, be it an individual or a manufacturer. To solve the problems effectively, power supply units and uninterruptible power supplies (UPS) were developed.

A power supply unit serves mainly to provide stable electricity, which includes an appropriate voltage, current, and power. Generally, an electronic product that is required to work over a long time (e.g., an industrial computer or server) needs a high-power power supply system or a power supply system with a standby power source. As power supply requirements vary from one electronic product to another, it is important to produce power supply units with different output specifications so that consumers have plenty of options to choose from. This, however, not only adds to the difficulty of production and warehousing, but also forces one who has replaced an existing electronic product with a different model or a model with different specifications to discard the existing power supply unit and purchase a new one, incurring additional expense and a waste of resources.

While some users may try to connect several individual power supply units in series or parallel, the connecting process is complicated, and the users must be able to identify the source power or the specifications of the direct-current power source involved in order to ensure normal operation of the power supply units. It is therefore difficult for an ordinary user to complete the required operation. Moreover, if it is desired to make a power supply unit output electricity of different power source specifications, a complex internal circuit structure is often required to enable adjustment of the power source specifications. Such a circuit structure, however, is difficult to design and manufacture and may cause inconvenience in maintenance and debugging.

In addition, the applicant has found that the problems stated above are shared by the existing electronic products (e.g., motor devices and electric vehicles). As the driver and power source unit of an electronic product are generally designed according to the operation requirements of the product, a change of product specifications is likely to render the existing driver and power source unit useless; in other words, the driver and the power source unit may have to be replaced or redesigned, which is extremely inconvenient. If it is desired to adapt the existing driver and power source unit to different power source specifications, more complicated circuit structures will be required to effect the intended change of power source specifications. The issue to be addressed by the present disclosure is to design a circuit structure that allows the power output specifications to be changed with ease, thereby solving the foregoing problems effectively.

### SUMMARY

Certain aspects of the disclosure direct to a circuit structure for switching a plurality of power supply units between a series-connected configuration and a parallel-connected configuration. The circuit structure is applicable to the driver of an electronic product and at least includes a first power supply unit, a second power supply unit, and a switch unit. The first power supply unit includes a first front diode, a first rear diode, and a first electricity element. The anode of the first front diode is connected to a positive electrode of the first electricity element while the cathode of the first front diode is electrically connected to a first end of an electricity output portion of the circuit structure. The cathode of the first rear diode is connected to a negative electrode of the first electricity element while the anode of the first rear diode is electrically connected to a second end of the electricity output portion. The second power supply unit includes a second front diode, a second rear diode, and a second electricity element. The anode of the second front diode is connected to a positive electrode of the second electricity element while the cathode of the second front diode is electrically connected to the first end of the electricity output portion. The cathode of the second rear diode is connected to a negative electrode of the second electricity element while the anode of the second rear diode is electrically connected to the second end of the electricity output portion. The switch unit has a first end connected to the anode of the first front diode and a second end connected to the cathode of the second rear diode. When the switch unit is in the closed-circuit state, the first power supply unit and the second power supply unit are in a series-connected configuration for outputting electricity to the electricity output portion. When the switch unit is in the open-circuit state, the first power supply unit and the second power supply unit are in a parallel-connected configuration for outputting electricity to the electricity output portion.

These and other aspects of the present disclosure will become apparent from the following description of the preferred embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, wherein:

FIG. 1 shows a circuit structure according to certain embodiments of the present disclosure.

FIG. 2 shows an equivalent circuit of the circuit structure in FIG. 1 while the switch unit is in the closed-circuit state.

FIG. 3 shows an equivalent circuit of the circuit structure in FIG. 1 while the switch unit is in the open-circuit state.

### DETAILED DESCRIPTION

The present disclosure is more particularly described in the following examples that are intended as illustrative only since numerous modifications and variations therein will be apparent to those skilled in the art. Various embodiments of the disclosure are now described in detail. Referring to the drawings, like numbers, if any, indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present disclosure. Additionally, some terms used in this specification are more specifically defined below.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein. No special significance is to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the disclosure or of any exemplified term. Likewise, the disclosure is not limited to various embodiments given in this specification.

Unless otherwise defined, all technical and scientific terms used herein have the same meaning as commonly understood by one of ordinary skill in the art to which this disclosure pertains. In the case of conflict, the present document, including definitions will control.

As used herein, “around”. “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “plurality” means two or more.

As used herein, the terms “comprising,” “including,” “carrying,” “having,” “containing,” “involving,” and the like are to be understood to be open-ended, i.e., to mean including but not limited to.

As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

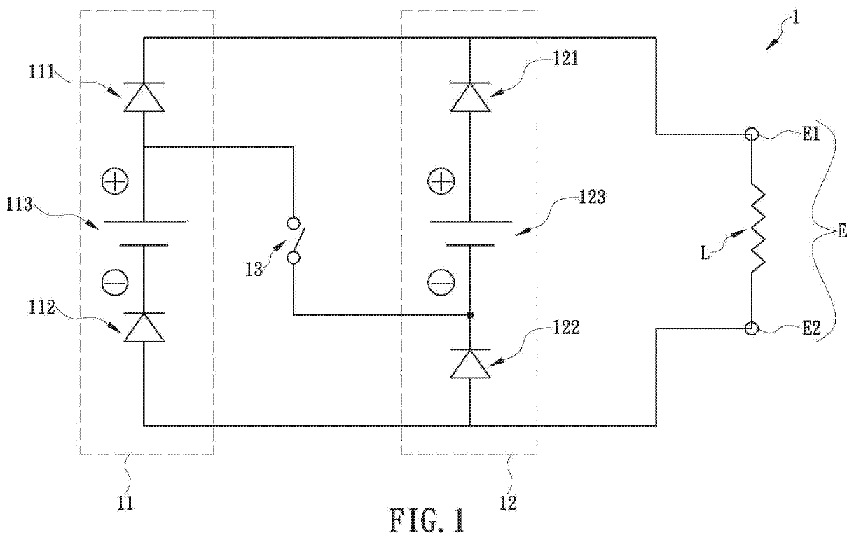

The present disclosure relates to a circuit structure applied to the driver of an electronic product (e.g., a driver for driving an electric vehicle or motor). The driver may also be referred to as an inverter, controller, frequency converter, or the like, and serves mainly to output electricity. The circuit structure is for switching a plurality of power supply units between a series-connected configuration and a parallel-connected configuration. Referring to FIG. 1, the circuit structure 1 at least includes a first power supply unit 11, a second power supply unit 12, and a switch unit 13. It is noted that the circuit structure 1 described herein is only a basic structure. A person skilled in the art may increase the number of the power supply units and of the switch unit or even provide the circuit structure 1 with additional electronic components and circuits (e.g., resistors, capacitors, current-limiting circuits, etc.) according to the technical features described below and/or to meet practical needs, provided that the circuit structure 1 has the essential structure disclosed herein and can produce the intended effects.

With continued reference to FIG. 1, the first power supply unit 11 includes at least a first front diode 111, a first rear diode 112, and a first electricity element 113. The anode of the first front diode 111 is connected to a positive electrode of the first electricity element 113. The cathode of the first front diode 111 is electrically connected to an end E1 of an electricity output portion E of the circuit structure 1. The cathode of the first rear diode 112 is connected to a negative electrode of the first electricity element 113. The anode of the first rear diode 112 is electrically connected to the other end E2 of the electricity output portion E. In certain embodiments, and by way of example only, the first electricity element 113 has an output voltage of 1.5 V and an output current of 1 A. The first electricity element 113 serves the main purpose of providing electricity, and its configuration may be adjusted according to product requirements. For instance, the first electricity element 113 may be a battery, a switching power, or a power supply.

With continued reference to FIG. 1, the second power supply unit 12 includes at least a second front diode 121, a second rear diode 122, and a second electricity element 123. The anode of the second front diode 121 is connected to a positive electrode of the second electricity element 123. The cathode of the second front diode 121 is electrically connected to the end E1 of the electricity output portion E. The cathode of the second rear diode 122 is connected to a negative electrode of the second electricity element 123. The anode of the second rear diode 122 is electrically connected to the end E2 of the electricity output portion E. In certain embodiments, and by way of example only, the second electricity element 123 has an output voltage of 1.5 V and an output current of 1 A.

With continued reference to FIG. 1, the switch unit 13 has a first end connected to the anode of the first front diode 111 and a second end connected to the cathode of the second rear diode 122. In certain embodiments, the switch unit 13 is a relay. In certain embodiments, the switch unit 13 may be a thyristor or a transistor instead, wherein the transistor may be a field-effect transistor (FET) or a bipolar junction transistor (BJT), depending on product requirements.

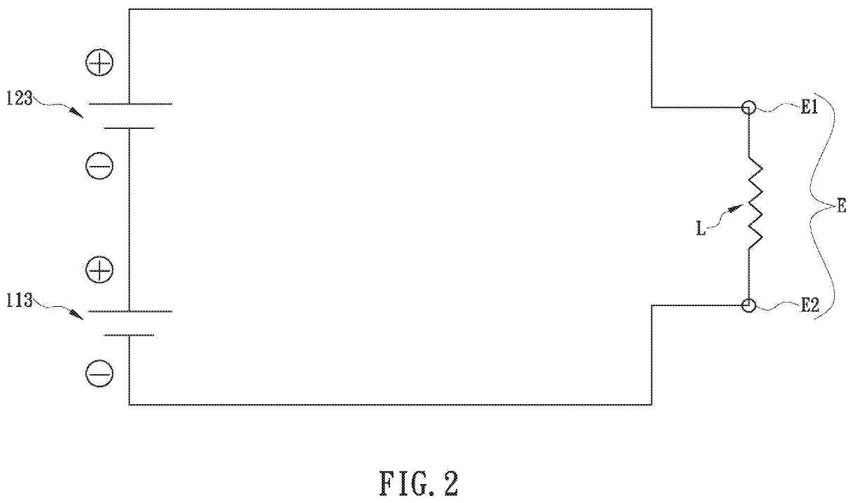

With continued reference to FIG. 1, when the switch unit 13 is in the closed-circuit state, the positive electrode of the first electricity element 113 is connected to the negative electrode of the second electricity element 123 such that the first electricity element 113 and the second electricity element 123 are connected in series. As a diode conducts electricity in one direction only (i.e., in the forward direction rather than the reverse direction), electric current from the positive electrode of the second electricity element 123 is prevented from flowing through the first front diode 111 to the negative electrode of the second electricity element 123, and electric current from the positive electrode of the first electricity element 113 is prevented from flowing through the second rear diode 122 to the negative electrode of the first electricity element 113. Thus, the first electricity element 113 and the second electricity element 123 are each kept from short-circuiting and jointly form the equivalent circuit in FIG. 2, allowing the load L connected to the electricity output portion E to receive a total electricity output of 3 V and 1 A from the first power supply unit 11 and the second power unit 12.

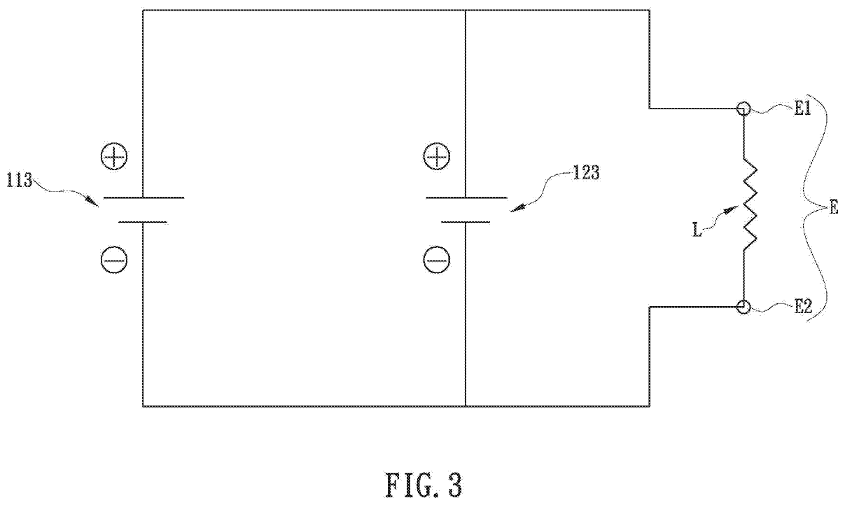

With continued reference to FIG. 1, when the switch unit 13 is in the open-circuit state, an open circuit is formed between the positive electrode of the first electricity element 113 and the negative electrode of the second electricity element 123; as a result, the first electricity element 113 and the second electricity element 123 are connected in parallel and form the equivalent circuit in FIG. 3, allowing the load L connected to the electricity output portion E to receive a total electricity output of 1.5 V and 2 A from the first power supply unit 11 and the second power unit 12. According to the above, the circuit structure 1 makes it possible to adjust the output electricity merely by changing the state of the switch unit 13. Moreover, thanks to the exceptional design of the circuit structure 1, a circuit employing the circuit structure 1 can be designed, manufactured, maintained, and debugged with ease. A manufacturer, therefore, can readily increase the number of the power supply units and of the switch unit to enable an even wider diversity of output electricity, thereby increasing the industrial applicability of the present disclosure. For example, the circuit structure 1 of the present disclosure not only can be applied to the internal circuit of a power supply unit to adapt the output electricity of the power supply unit to an external electronic device, but also can be applied to a motor device or an electric vehicle in order to adjust the power supplied to the motor driver or the electric vehicle.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A circuit structure for switching a plurality of power supply units between a series-connected configuration and a parallel-connected configuration, to be applied to a driver of an electronic product, the circuit structure comprising:
an electricity output portion having a first end and a second end;
a first power supply unit comprising a first front diode, a first rear diode and a first electricity element, wherein the first front diode has an anode connected to a positive electrode of the first electricity element and a cathode electrically connected to the first end of the electricity output portion, and the first rear diode has a cathode connected to a negative electrode of the first electricity element and an anode electrically connected to the second end of the electricity output portion;
a second power supply unit comprising a second front diode, a second rear diode, and a second electricity element, wherein the second front diode has an anode connected to a positive electrode of the second electricity element and a cathode electrically connected to the first end of the electricity output portion, and the second rear diode has a cathode connected to a negative electrode of the second electricity element and an anode electrically connected to the second end of the electricity output portion; and
a switch unit having a first end connected to the anode of the first front diode and a second end connected to the cathode of the second rear diode, wherein the switch unit has a closed-circuit state, in which the first electricity element and the second electricity element are connected in series and output electricity to the electricity output portion, and an open-circuit state, in which the first electricity element and the second electricity element are connected in parallel and output electricity to the electricity output portion.

2. The circuit structure of claim 1, wherein the driver is a motor driver.

3. The circuit structure of claim 1, wherein the driver is an electric vehicle driver.

4. The circuit structure of claim 1, wherein the switch unit is a relay.

5. The circuit structure of claim 2, wherein the switch unit is a relay.

6. The circuit structure of claim 3, wherein the switch unit is a relay.

7. The circuit structure of claim 1, wherein the switch unit is a field-effect transistor.

8. The circuit structure of claim 2, wherein the switch unit is a field-effect transistor.

9. The circuit structure of claim 3, wherein the switch unit is a field-effect transistor.

10. The circuit structure of claim 1, wherein the switch unit is a bipolar junction transistor.

11. The circuit structure of claim 2, wherein the switch unit is a bipolar junction transistor.

12. The circuit structure of claim 3, wherein the switch unit is a bipolar junction transistor.

13. The circuit structure of claim 1, wherein the switch unit is a thyristor.

14. The circuit structure of claim 2, wherein the switch unit is a thyristor.

15. The circuit structure of claim 3, wherein the switch unit is a thyristor.
